(19) United States
(12) Patent Application Publication
(10) Pub. No.: US 2013/0163179 A1
(43) Pub. Date: Jun. 27, 2013

(54) ELECTRONIC DEVICE WITH DUMMY HARD DISK DRIVE

(71) Applicants: ZHEN-XING MA, Shenzhen City (CN); ZHENG-HENG SUN, Tu-Cheng (TW)

(72) Inventors: ZHEN-XING MA, Shenzhen City (CN); ZHENG-HENG SUN, Tu-Cheng (TW)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/434,867

(22) Filed: Mar. 30, 2012

(30) Foreign Application Priority Data
Dec. 23, 2011 (CN) 201110437311.0

(51) Int. Cl. H05K 7/00; B32B 3/06; H05K 5/02

(52) U.S. Cl. 361/679.33; 428/54

(57) ABSTRACT

A dummy hard disk drive (HDD) includes a main body and two arms extending along opposite end surfaces of the main body. The arms each form a pin for fixing the dummy HDD in an HDD bracket. A connecting portion is formed on a side of the main body for connecting cables.

### BACKGROUND

1. Technical Field

The present disclosure relates to an electronic device having a dummy hard disk drive (HDD).

2. Description of Related Art

An electronic device, such as a computer or a server, includes a plurality of brackets for mounting HDDs. A dummy HDD may be fitted in each bracket to avoid the bracket from being deformed or damaged when manufacturing or transporting the electronic device. When it is time to install a real HDD in the bracket, the dummy HDD is removed. However, when a dummy HDD is fixed in the bracket, the cables for a real HDD cannot be connected to any elements, and are just left to dangle and create a mess.

### BRIEF DESCRIPTION OF THE DRAWINGS

Many aspects of the present embodiments can be better understood with reference to the drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an exploded, isometric view of an embodiment of an electronic device.

FIG. 2 is an assembled, isometric view of FIG. 1.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

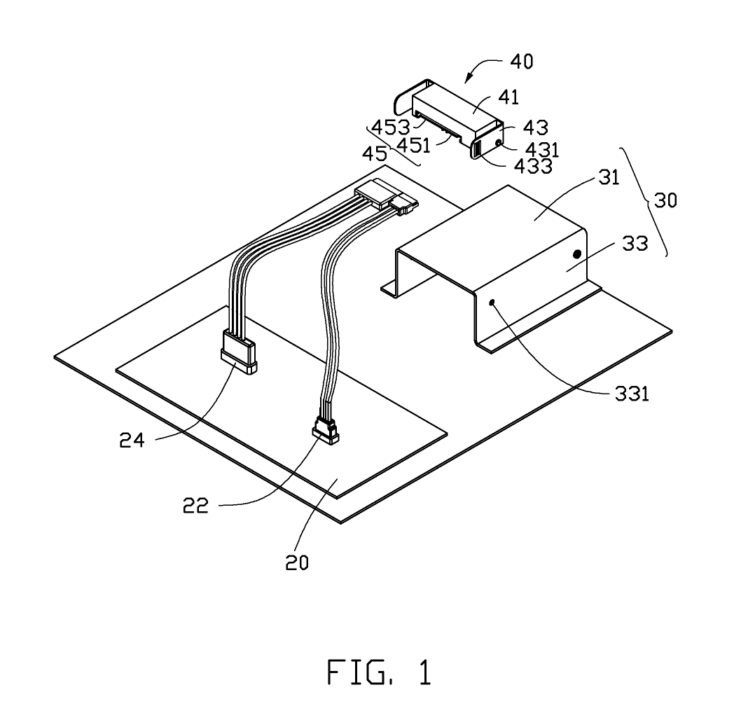

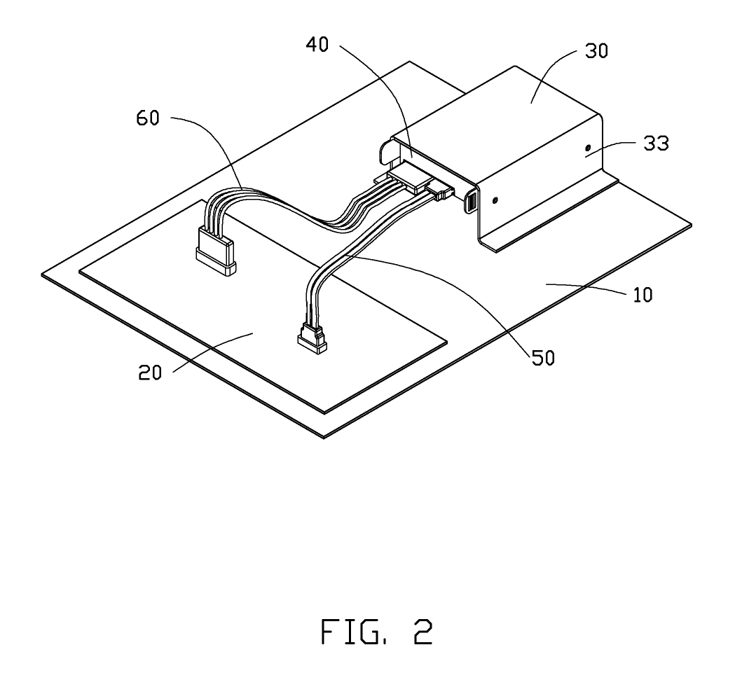

Referring to FIGS. 1 and 2, an embodiment of an electronic device includes a mounting plate 10, a circuit board 20 set on a first side of the mounting plate 10, a bracket 30 set on a second side of the mounting plate 10, and a dummy hard disk drive (HDD) 40.

The circuit board 20 includes a first socket 22 and a second socket 24. In this embodiment, the first socket 22 is a signal socket, and the second socket 24 is a power socket.

The bracket 30 is substantially U-shaped, and includes a top plate 31 and two side plates 33 extending down perpendicularly from opposite sides of the top plate 31. The side plates 33 are fixed on the mounting plate 10. Each side plate 33 defines two mounting holes 331 for mounting an HDD.

The dummy HDD 40 includes a substantially rectangular main body 41, and two resilient arms 43 extending from opposite ends of a first side to a second side of the main body 41. The arms 43 are parallel to end surfaces of the main body 41. A pin 431 protrudes out from each arm 43, away from the main body 41. A handle 433 is formed on a distal end of each arm 43. A connecting portion 45 is formed on the second side of the main body 41. The connecting portion 45 is a dummy connector, and includes a dummy signal connector 451 and a dummy power connector 453. The dummy signal connector 451 and the dummy power connector 453 are non-functioning analogs of the real connectors.

In use, the handles 433 are operated to deform the arms 43 toward each other, the dummy HDD 40 is inserted into the bracket 30. The arms 43 are released and restore to make the pins 431 engage in the corresponding mounting holes 331. A first cable 50 is connected between the first socket 22 and the dummy signal connector 451. A second cable 60 is connected between the second socket 24 and the dummy power connector 453. In this embodiment, the first cable 50 is a signal cable, and the second cable 60 is a power cable.

In this embodiment, the electronic device includes the dummy HDD 40 arranged in the HDD bracket 30, and the dummy HDD 40 includes a connecting portion 45 for connecting the cables 50 and 60, which maintains the cables 50 and 60 in an orderly manner.

It is to be understood, however, that even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A dummy hard disk drive (HDD), comprising:
a main body;
two resilient arms extending from opposite ends of a first side of the main body toward a second side of the main body opposite to the first side, a pin protruding out from each of the arms; and
a connecting portion formed on the second side of the main body.

2. The dummy HDD of claim 1, wherein the arms are parallel to end surfaces of the main body connected between the first and second sides of the main body.

3. The dummy HDD of claim 1, wherein the connecting portion is a dummy connector.

4. The dummy HDD of claim 3, wherein the connecting portion comprises a dummy signal connector and a dummy power connector, the dummy signal connector and the dummy power connector are non-functioning analogs of the real connectors.

5. The dummy HDD of claim 1, wherein a handle is formed on a distal end of each of the arms, for operating the arms to be deformed.

6. An electronic device comprising:
a mounting plate;
a circuit board set on a first side of the mounting plate, wherein the circuit board comprises a socket, a first end of a cable is connected to the socket;
a bracket set on a second side of the mounting plate; and
a dummy hard disk drive fixed in the bracket, wherein a connecting portion is formed on the dummy hard disk drive for connecting a second end of the cable.

7. The electronic device of claim 6, wherein the dummy hard disk drive comprises a main body and two resilient arms extending along opposite ends of the main body from a first side to a second side of the main body, a pin protrudes out from each of the arms, the bracket comprises two side plates fixed to the mounting plate, each of the side plates defines a mounting hole, the arms are mounted to the side plates respectively through the pins engaging in the mounting holes.

8. The electronic device of claim 7, wherein the connecting portion is formed on the second side of the main body.

9. The electronic device of claim 8, wherein the connecting portion is a dummy connector.

10. The electronic device of claim 9, wherein the connecting portion comprises a dummy signal connector and a dummy power connector, the dummy signal connector and the dummy power connector are non-functioning analogs of the real connectors.
